(19) United States
(12) Patent Application Publication
(10) Pub. No.: US 2010/0226168 A1
(43) Pub. Date: Sep. 9, 2010

(54) Programming methods for phase-change memory

(76) Inventor: Semyon D. Savransky, Newark, CA (US)

Correspondence Address: Daniel R. Shepard;Contour Semiconductor, Inc., Building 5, Ste 105, 101 Billerica Avenue, North Billerica, MA, 01862, US

(21) Appl. No.: 12/660,783

(22) Filed: Mar. 3, 2010

Related U.S. Application Data
(60) Provisional application No. 61/209,196, filed on Mar. 4, 2009.

(51) Int. Cl. G11C 11/00; G11C 7/00

(52) U.S. Cl. 365/163; 365/189.16; 365/148

(57) ABSTRACT

Set pulses with finite rise time that heat up phase change alloy between about nucleation temperature and about average of crystallization and melting temperatures are proposed for programming phase change memory from reset to set state in order to minimize energy during this transition and to achieve uniform set state distribution. Non-square reset pulses with finite rise time that heat up phase change alloy at or above melting temperature are proposed for programming phase change memory from set to reset state in order to improve cell endurance.

### CROSS REFERENCE TO RELATED APPLICATIONS

This application claims priority to and the benefit of, and incorporates herein by reference in its entirety, U.S. Provisional Patent Application No. 61/209,196, which was filed on Mar. 4, 2009.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

### Field of the Invention

The invention relates to a phase-change memory (PCM) and, in particular, to programming methods for PCM into set and reset states.

Principle of PCM Operation.

Phase-change memories consist of several PCM cells are non-volatile memory devices that store data using a phase-change alloy (PCA), such as Ge—Sb—Te, the electric resistance of which varies upon a phase transition between two states that is caused by a change in temperature. Phase-change memory (PCM) can be read and programmed very quickly and do not require power to maintain their state. Therefore, phase change devices are very useful devices for storing data (e.g., as a computer memory device). PCM cells have many of the advantages of both volatile memories such as dynamic random access memories (DRAMs) and non-volatile memories (Flash).

The resistance of the PCA in the reset state is greater than the resistance of the PCA in the set state. In order to have good sense margin the ratio of set and reset resistances in PCM should be as high as possible. It is desirable also to spend small energy during PCM programming, to have high endurance of PCM, and to have tight distributions of parameters for set and reset PCM cells in a memory array.

The pulses or pulse trains produce current through PCM in all prior art methods and embodiments of PCM programming methods. This current heats up active PCA to or above crystallization temperature Tx for the set state and to or above melting temperature Tm for the reset state due to the Joule effect.

The PCA may change back and forth between a crystalline state and an amorphous state during a programming pulse when the current flows through a PCM. As an example, a PCA may be heated to its melting point by applying a relatively high current (e.g., 3 mA) pulse to the PCA for a relatively short duration of time (e.g., 10 ns). The PCA may then be rapidly cooled, which changes the PCA to a highly resistive, amorphous state, named as reset state. When PCA in the reset state is heated above its crystallizing temperature by applying a relatively low current pulse (e.g., 500 uA) for relatively long time (e.g., 1 us) it changes to a lower resistive, crystalline state, named as set state.

### DESCRIPTION OF THE RELATED ART

Lai and Lowrey, as reported in the paper “OUM-A 180 nm nonvolatile memory cell element technology for stand alone and embedded applications” published in Electron Devices Meeting, 2001. IEDM Technical Digest, 2-5 Dec. 2001 p. 36.5.1-36.5.4, used long (e.g., 500 ns) square pulse (FIG. 1A) to achieve a set state of phase change memory. Advantage of such set pulse is small energy for PCM programming in set state, disadvantage that not all cells in big array can be programmed with the same pulse. Lai and Lowrey, as reported in this paper used short (e.g., 100 ns) square pulse with high amplitude to melt PCA and then quench it in the reset state. Advantage of such reset pulse is simplicity of pulse generating circuit, disadvantage that some of cells in big array can be overheated because of difference in melting temperature Tm between different PCM cells. This causes low endurance of such PCM cells.

The following sections give comprehensive review of set and reset pulses proposed for PCM in the prior art that reflect improvements of Lai—Lowrey programming methods.

Prior Art: SET Pulses.

During set pulse active volume of PCA should be obtained in mostly crystalline state usually from previously mostly amorphous state. The amorphous state can be solid with high viscosity (e.g., glass) or liquid with small viscosity (e.g., melt of PCA). As early as the eighteenth century, the idea of fabricating polycrystalline materials by first forming glass and then nucleating and crystallizing it to form a highly crystalline material was proposed by Rene Antoine Ferchault de Réaumur, a famous French chemist. Most of set pulses described in this section are based on this concept.

Lowrey proposed in U.S. Pat. No. 6,570,784 “Programming a phase-change material memory”(May 2003) to use truncated trapezoidal pulse with short rise time and long fall time trailing edge (FIG. 1B) for uniform programming of set cells with long trailing edge (100 ns-1 us) and maximum amplitude equal to the reset pulse amplitude (e.g. 1 mA). In this case PCA in PCM cells is melted and then slow cool down, so temperature in each PCM will pass optimal crystallization temperature interval. Such pulse ensures a better set condition for marginal PCM cells and adequately narrow set distributions, which results in improved read margin. Such trapezoidal pulse required a big energy (because it supposes to melt portion of PCA) and long time during PCM programming.

Lowrey also proposed in U.S. Pat. No. 6,687,153 “Programming a phase-change material memory” (February, 2004) to use triangle set pulse (FIG. 1C) with maximum amplitude equal to the reset pulse amplitude. This pulse does not provide advantages to compare with truncated trapezoidal pulse described in U.S. Pat. No. 6,570,784.

Such set pulses patented by Lowrey are required huge energy for programming a PCM cell into set state and therefore not applicable for PCM memory usage in mobile applications.

Bedeschi, et.al., as reported in the paper “Set-Sweep Programming Pulse for Phase-Change Memories ” published in Circuits and Systems, Proceedings of ISCAS 2006: IEEE International Symposium on 21-24 May 2006 Page(s):967-970 and in the paper “Staircase-down SET programming approach for phase-change memories” published in Microelectronics Journal, Volume 38, Issues 10-11, October-November 2007, Pages 1064-1069, use staircase-down set sweep (FIG. 1D) which is digital realization of Lowrey's U.S. Pat. No. 6,570,784.

Hye-jin Kim, et.al. in US Patent Application 20080106930 “PRAM and method of firing memory cells” (May 8, 2008) and Te-Sheng Chao, et.al. in US Patent Application 20080151613 “Programming method for phase change memory” (Jun. 26, 2008) proposed pulses very similar to Lowrey's U.S. Pat. No. 6,570,784 and Bedeschi's papers idea of two or more states pulse sweep (FIG. 1E) to stimulate PCM work after fabrication (so-called firing).

Ming-Jung Chen, et.al. use in US Patent Application 200800219046 “Writing method and system for a phase change memory” (Sep. 11, 2008) pulse train that keep PCM between crystallization and melting temperatures during set programming. Such pulse train has no advantages to compare with Lai—Lowrey single pulse in terms of stability of PCM programming into the set state but requires more complicated write circuits design.

Chang-Soo Lee et.al. use in US Patent Application 20080144363 “Method of testing PRAM device” (Jun. 19, 2008) square reset and staircase-down set pulses to test PCM array (FIG. 1F).

Byung-Gil Choi, et. al. proposed in U.S. Pat. No. 7,274,586 “Method for programming phase-change memory array to set state and circuit of a PCM device” (September 2007) to use set pulses train (FIG. 1G) in order to improve set PCM programming. Such pulses also do not allow perform uniform set programming with small energy and required quite complicated write circuits to implement them. This set pulses train do not have any significant advantage to compare with Lowrey- Bedeschi-Chao pulses.

Happ and Phillipp propose in US Patent Application 20090003044 “Program Method with Locally Optimized Write Parameters” (January 2009) to use set pulse with trailing slope termination (FIG. 1H). Actually such pulses used for long time in other companies that develop PCM, hence this patent application does not have novelty.

Prior Art: RESET Pulses.

During reset pulse active volume of PCA should be obtained in mostly the solid amorphous state usually from previously mostly crystalline state. Most of reset pulses described in this section are based on vitrification of the melt.

Savransky proposed in white paper “Some Peculiarities of Reset Process and Reliability of Chalcogenide Phase-Change Non-Volatile Memory” (August 2005) published in the WWW, see http://www.geocities.com/chalcogenide_glasses/Presentations/SDS_{—}2005_Reliability.pdf reset pulse with annealing portion (FIG. 11) to decrease drift in PCA.

Phillipp, et.al. proposed in US Patent Application 20080273371 “Memory Including Write Circuit For Providing Multiple Reset Pulses” (Nov. 6, 2008) to use few square reset pulses with decreasing amplitude to PCM cells with various critical dimension in array (FIG. 1J). The second and following reset pulses with amplitude smaller than the amplitude of the first reset pulse can decrease the resistance of a PCM programmed to reset state by the first reset pulse, therefore decrease the read margin. On the other hand, the amplitude of the first reset pulse can be too high for the some PCM cells that can be programmed by the second and following reset pulses, therefore the first pulse reduce endurance of such PCM cells.

Phillipp, et.al. proposed in US Patent Application 20090003035 “Conditioning Operations for Memory Cells” (January 2009) to use few successive square reset pulses (FIG. 1K) with the same amplitude to condition a memory cell. Such reset pulses train is longer than a single reset pulse, and leads to smaller endurance of PCM.

Ming Hsiu Lee and Chou Chen proposed in U.S. Pat. No. 7,272,037 “Method for programming a multilevel phase-change memory device” (September 2007) different pulses for reset state with variable threshold switching voltage. Each of their pulses required to melt PCA and then cool down in high resistive state. The threshold switching voltage (one of characteristics of the reset state) depends on cooling profile of their pulses. Except one triangle pulse (FIG. 1L) all their pulses has essentially zero leading portion. It should be noted that triangle pulse with long trailing edge as shown in the U.S. Pat. No. 7,272,037 is not suitable for programming PCM into reset state.

Savransky proposed in US provisional patent application 61/096,864 “Method of programming of the phase-change memory and associated devices and materials” (September 2008) to use reset pulses that allows preparation of solid amorphous PCA below the melting point.

Jun-Soo Bae et. al. proposed US Patent Application 2009/0073754 reset pulses with rising time longer than failing time for MLC programming of PCM.

Unresolved Problems.

In a memory array having a plurality of PCM cells, signal loads and parasitic resistances may vary among the individual PCM cells, depending on cell arrangements within the memory array. Further, PCM cells may vary because of, for example, differences in manufacturing processes as the area of the memory array increases. As the result levels of set and/or reset currents vary between or among different PCM cells. This may be undesirable, since it is impossible to change all PCM cells in the memory array to a desired state using single level of set current or single level of reset current respectively. In other words, if one level of programming current is applied, some of PCM cells actually change a state, but other PCM cells may not change a state. Also, resistance values may vary among the PCM cells that changed the state under application of single level programming current. This may cause errors in PCM array operation.

Although some activity to optimize reset pulse is ongoing as outlined in the abovementioned documents, the demand to optimize set pulse is stronger, because usually set distribution of PCM cells is large than reset distribution as it is shown for example by Pirovano, et.al. in the paper “Phase-change Memory Technology with Self-aligned μTrench Cell Architecture for 90 nm Node and Beyond” published in Solid-State Electronics, V.52, 1467 (2008). For example PCM cells may be programmed into the set state due to application of known set pulse but values of set resistances of these PCMS may vary more than 70%. Further, PCM cells may be programmed into the reset state due to application of known reset pulse but values of reset resistances of these PCMS may vary more than 50% as it shown in FIG. 2.

As the process variations (e.g., area of electrode/phase change alloy) increase with PCM size decrease and the operating parameters (e.g., operating temperature, voltage, etc.) vary, then requirement to achieve the desired resistances become more difficult. Therefore, it is demanding to accurately and reliable program a big array of PCM cells.

As PCM size decreases achieve good memory reliability becomes more difficult. Therefore, it is demanding to increase endurance PCM cells.

In view of the foregoing, there is a need for methods for accurately programming PCM in a set state, and methods for programming PCM in a reset state without endurance deterioration.

### SUMMARY OF THE INVENTION

Broadly speaking, the embodiments of the present invention fill industry needs by providing methods for accurately programming a phase change memory into set state with small energy consumption and for accurately programming a phase change memory into reset state without deterioration endurance. It should be appreciated that the embodiments of the invention can be implemented in numerous ways, including as a process, an apparatus, a system, or a device.

SET Pulses

In some embodiments a set pulse for PCM comprising a leading portion, a flat intermediate portion and a trailing portion. The leading portion of the set pulse with finite duration allows mostly complete nucleation and crystals formation of PCA after well-controlled threshold switching event. A nano-crystals growth and coalescence is mostly completed during the intermediate flat portion of the set pulse with small variation of the applied signal. During the trailing edge a stabilization of morphology of PCA nano-crystals is mostly completed and PCM cools down. In some embodiments various rates of applied signal increase occurs during the leading portion of the set pulse. In some embodiments various rates of applied signal decrease occurs during the trailing portion of the set pulse.

While duration and energy of proposed set pulses are equal or smaller than duration and energy of previously known set pulses the proposed set pulses lead to more uniform distribution of set resistance and, hence, to possibility to create large PCM arrays.

RESET Pulses

It is proposed in some embodiments to slow down a leading portion of a reset pulse near the melting point Tm in order to avoid overheating of PCM. Relatively slow portion of the leading portion of the reset pulse allows uniform temperature distribution during latent heat of PCA. Formation of PCA in solid amorphous state according to embodiments occurs through melting of active volume of PCA. It is proposed also in some embodiments to have an intermediate flat portion of a reset pulse with duration sufficient for mixing and a homogenization of the melt. It is proposed also in some embodiments to have a trailing portion of a reset pulse with duration sufficient for annealing amorphous PCA in order to stabilize PCA properties.

While duration and energy of proposed reset pulses are equal or smaller than duration and energy of previously known reset pulses the proposed reset pulses lead to higher PCM endurance.

In both cases proposed programming pulses for set and reset states reflect nature of processes in PCA during transition between mostly amorphous and mostly crystalline states rather than “blind” set and reset pulses used in some previous PCM patents and patent applications.

### BRIEF DESCRIPTION OF THE DRAWINGS

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIGS. 1A-1L show various programming (set and reset) pulses in prior art.

FIG. 2 shows the set and reset distributions in a PCM array.

FIG. 3A shows processes in PCA during PCM programming and PCA structures in different states.

FIG. 3B shows temperature dependences of different processes during set pulse and characteristic temperatures of PCA.

FIGS. 4A-4J show various timing diagrams for set pulses in accordance with embodiments of the present invention.

FIGS. 5A-5G show various timing diagrams for reset pulses in accordance with embodiments of the present invention.

FIG. 6 shows an example of PCM array with write circuit and other interface devices.

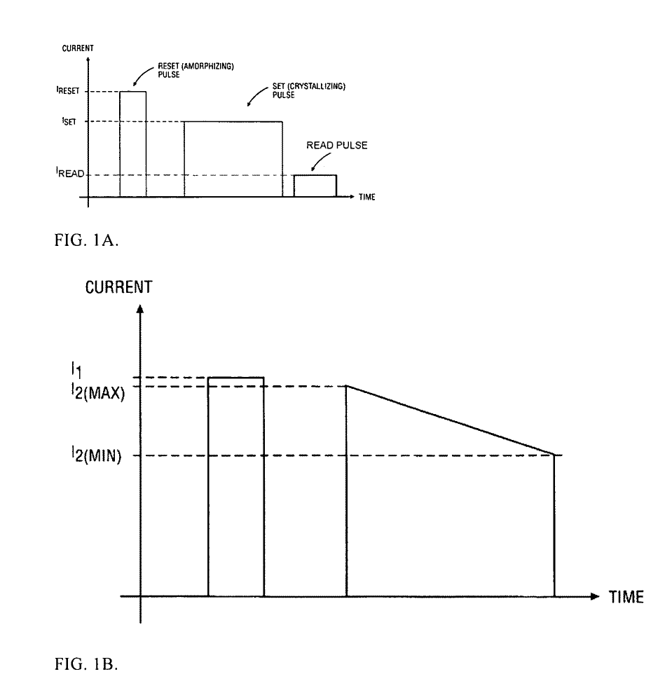

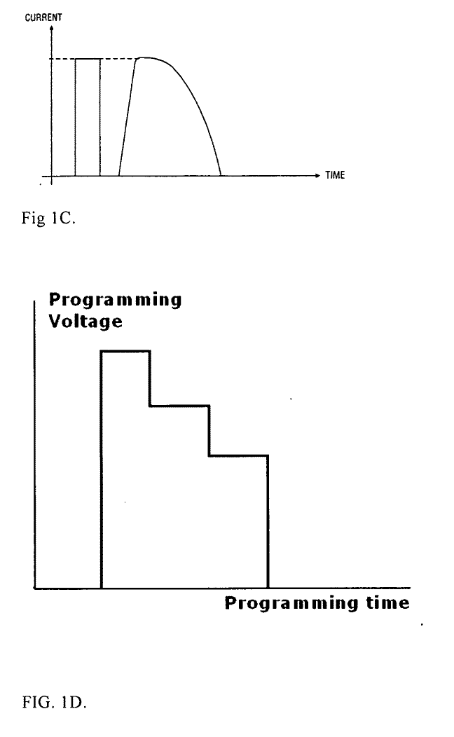

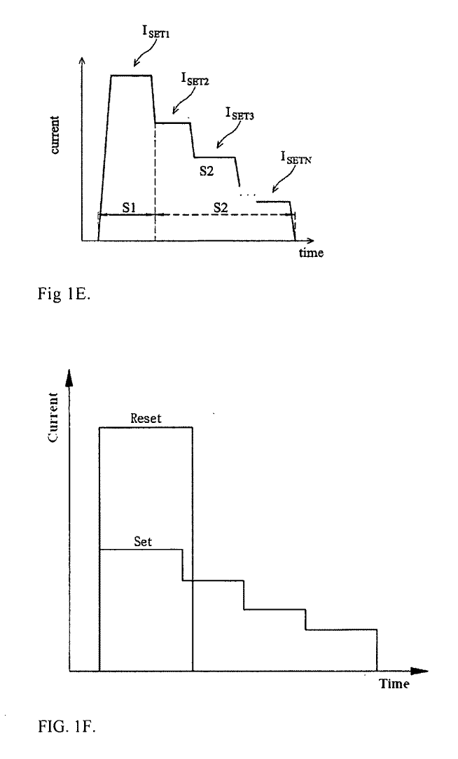

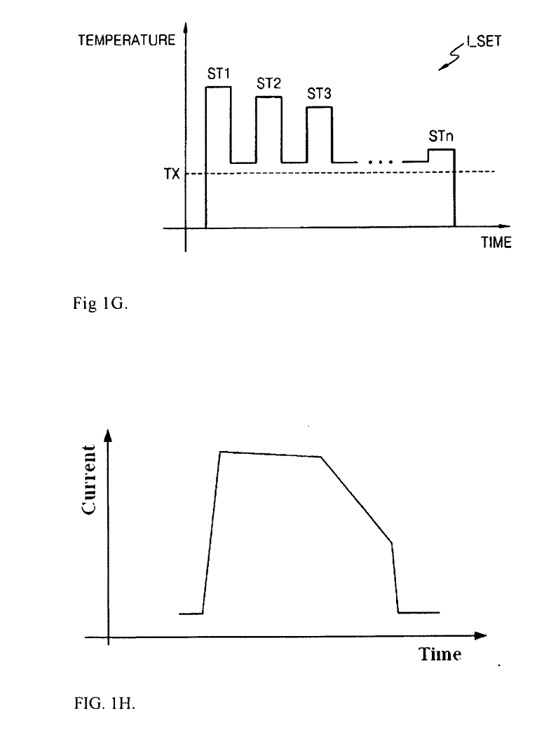

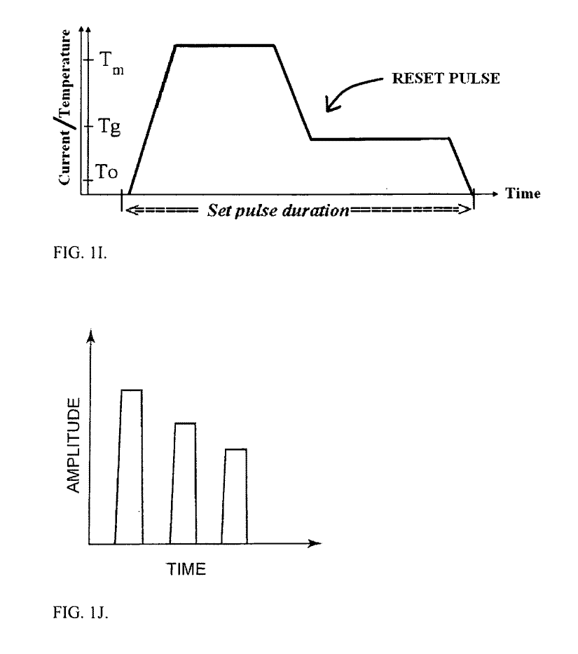

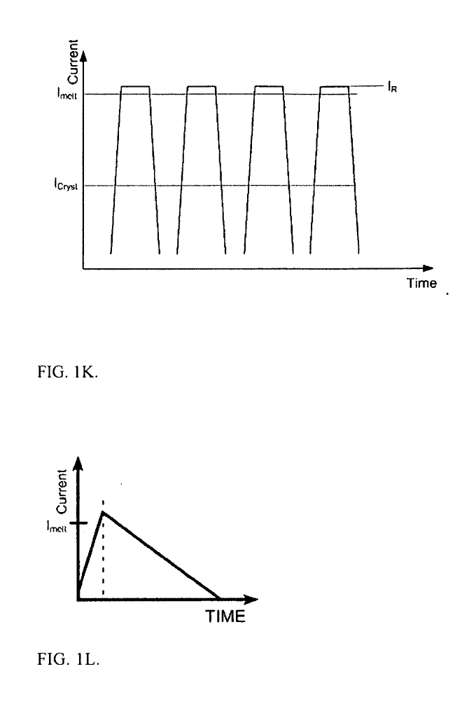

FIG. 1 show temperature or current along the vertical axis. It should be understood that the vertical axis could also show the voltage, energy, heat, light or other type of input amplitude of the respective pulse profiles.

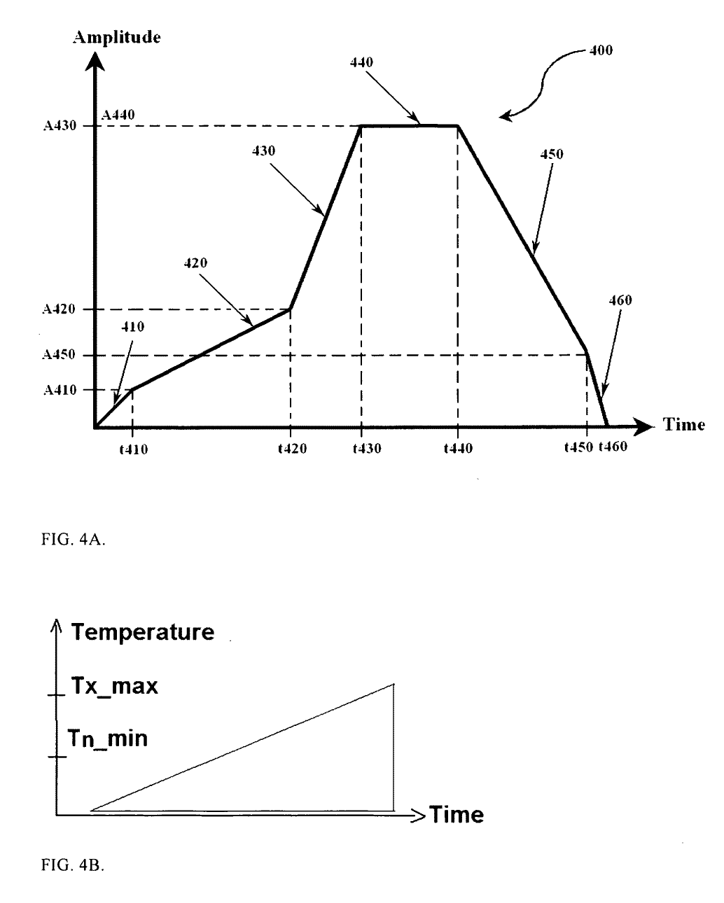

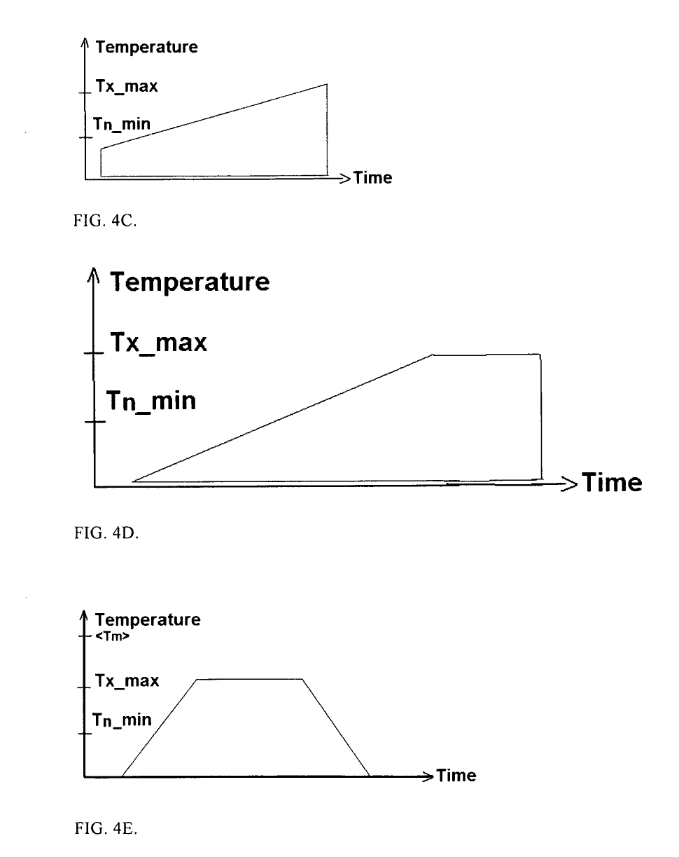

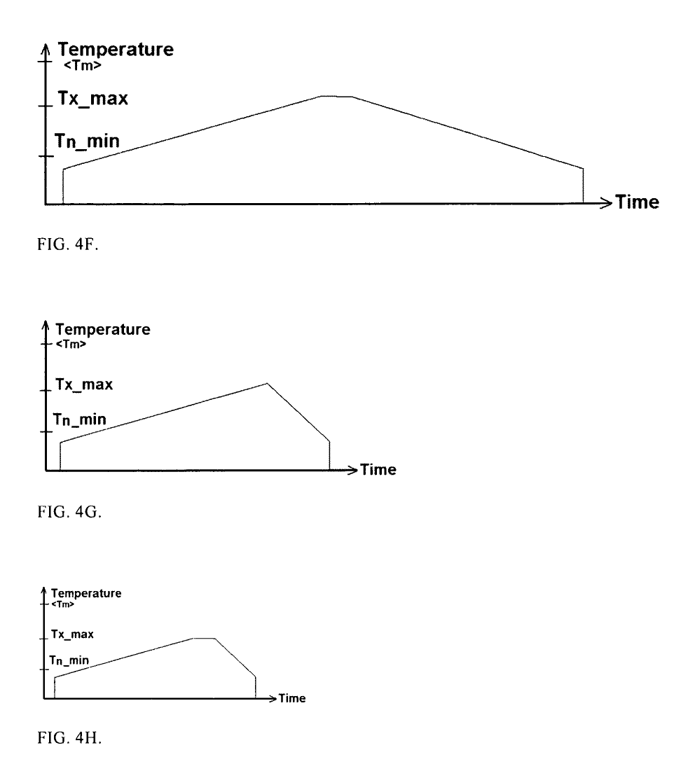

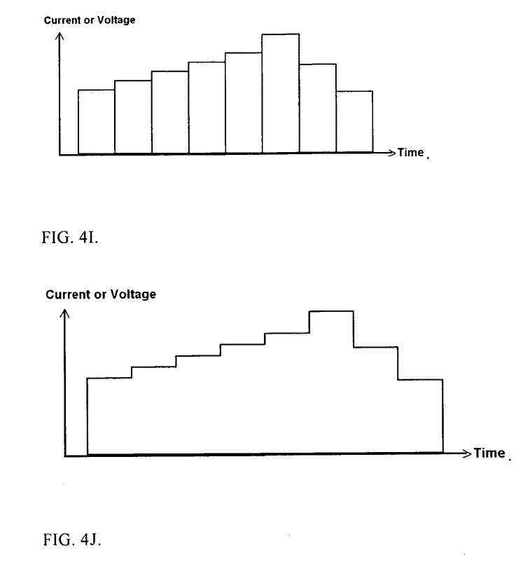

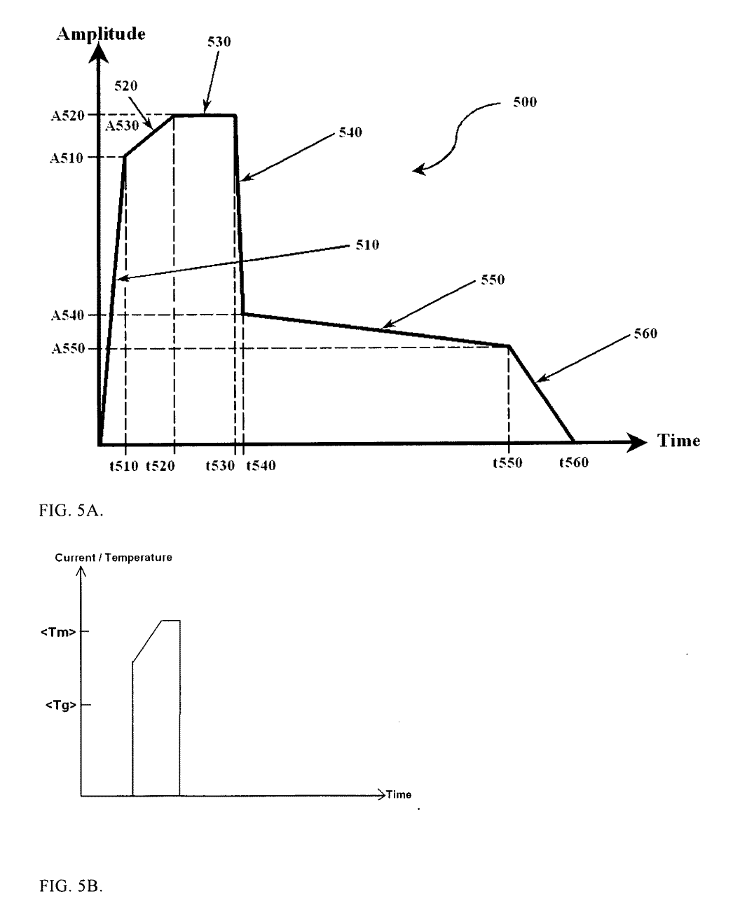

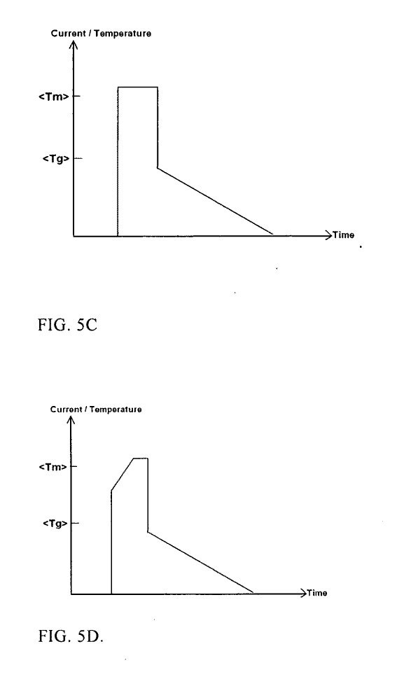

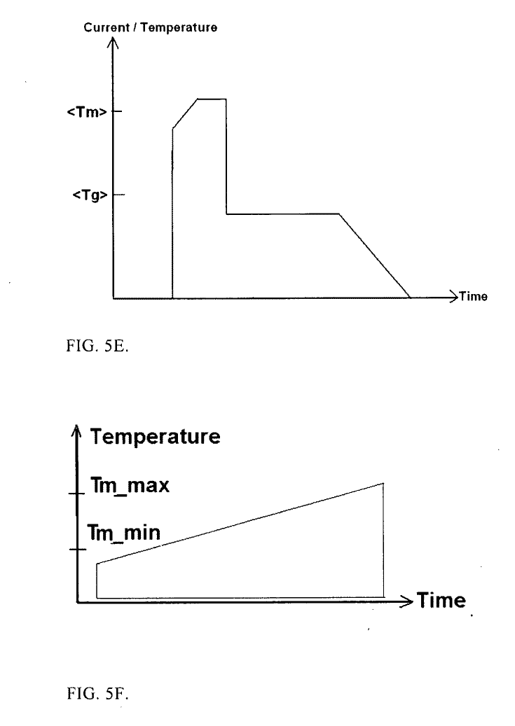

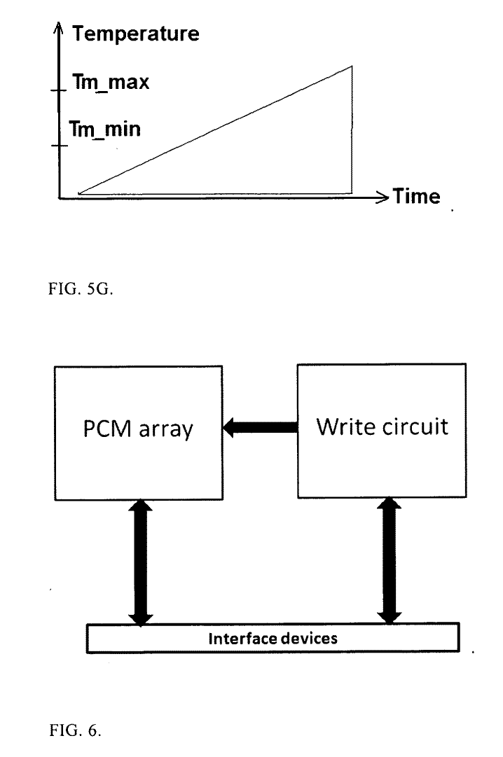

The vertical axis shows the amplitude in FIGS. 4 and 5. It should be understood that the vertical axis could also show the current, voltage, energy, temperature, heat, light, pressure or other type of input amplitude of the respective pulse profiles in these figures. The vertical axis shows the temperature in FIG. 6. It should be understood that the vertical axis could also show the current, voltage, energy, temperature, heat, light, pressure or other type of input amplitude of the respective pulse profiles in these figures.

### DESCRIPTION OF THE EXEMPLARY EMBODIMENTS

PCM Programming.

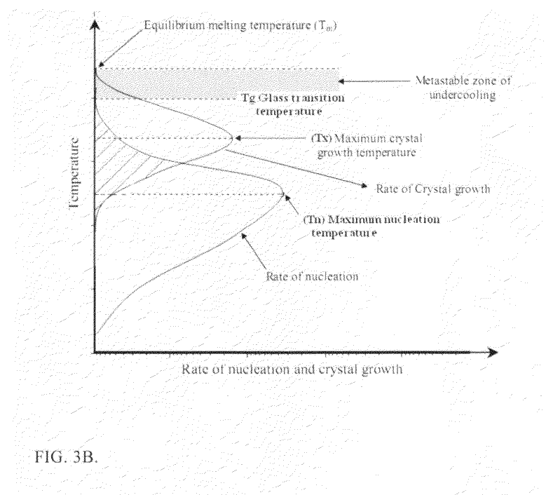

PCM can be programmed to low resistance (set, mostly crystalline) state and to high resistance (reset, mostly amorphous) state due to structural transformation in PCA as shown in the FIG. 3A. Transition from the set state to the reset state occurs due to PCA melting and fast quenching. Transition from the reset state to the set state occurs due to PCA nucleation and crystallization which are strongly depend on the temperature as shown in FIG. 3B.

SET State.

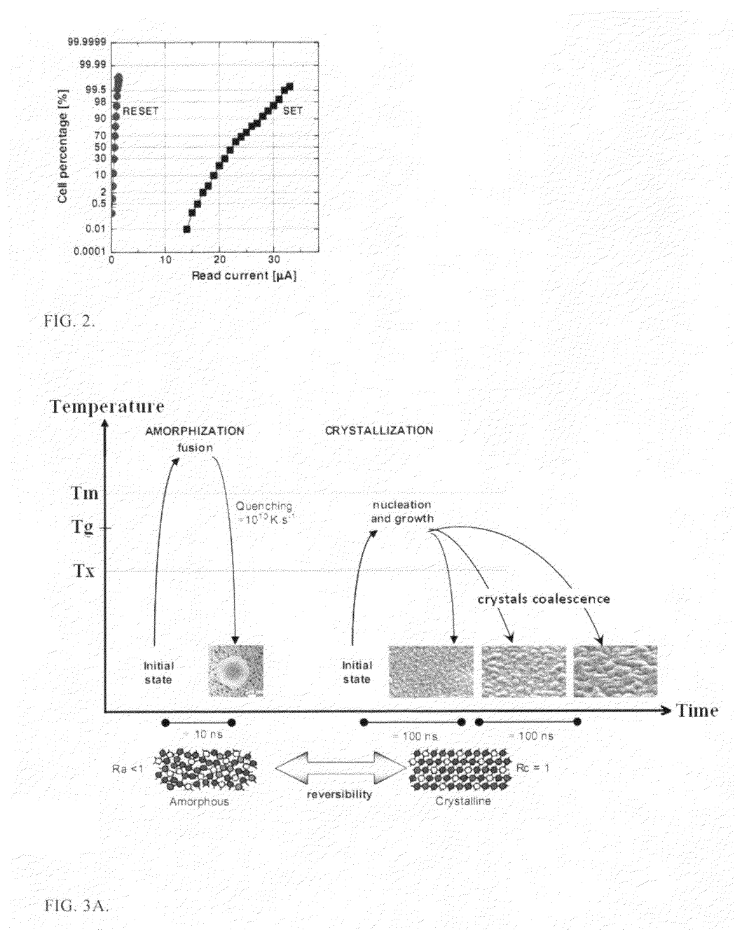

The programming from reset (amorphous) state to set state by electrical pulses includes threshold switching event that occurs in modern PCM at voltages between 0.3V and 10V and currents between 0.1 uA and 250 uA. The value and the uncertainty of threshold switching voltage in PCA depend on the rate of applied signal. The current through PCM immediately after the threshold switching depends on actual threshold switching voltage value and load line for the PCM in an array. During and after the threshold switching event two additional processes must occur in any amorphous material (including PCA), namely nucleation and crystal grown in order to crystallize the amorphous material. These processes are strongly temperature-dependent and the maximum rate of nucleation occurs at lower temperature than the maximum rate of crystallization (FIG. 2). Moreover, usually the nucleation is the bottleneck for programming PCM into set state for PCA like Ge—Sb—Te.

All prior art methods and embodiments of PCM programming to set state did not specify four crucial features, namely a) approach threshold switching voltage with finite speed of change applied signal with time; b) the critical step of keeping PCA between the minimal nucleation temperature Tn and the average crystallization temperature Tx for some period of time; c) the speed of heating up active PCA to the crystallization temperature Tx; and d) coalescence of PCA nano-crystals.

As the result of this ignorance the set state distribution of a PCM array is quite wide (FIG. 2) that limits the usable array size and increases PCM cost.

The programming set pulse profile describes the shape of the pulse as shown in FIG. 4.

The set pulses shown in FIG. 4 start at time zero and zero amplitude and finish at zero amplitude. Any arbitrary points can be selected for the set pulse start and end in one or more embodiments.

Referring to FIG. 4A, the end of the first leading portion of the set pulse 410 corresponds to the threshold switching event. The amplitude of the first leading portion of the set pulse 410 (value between zero and A410) for the threshold switching voltage is between 0.3V and 10V and for the threshold switching current is between 1 pA and 300 uA in one or more embodiments.

The duration of the first leading portion of the set pulse 410 (time between zero and t410) corresponds to the time of threshold switching event. The duration of the first leading portion of the set pulse 410 is below 1 us in one or more embodiments. The duration of the first leading portion of the set pulse 410 is below 150 ns in one or more preferred embodiments.

The parameters of the first leading portion of the set pulse 410 are selected in the way that ratio A410/t410 is between 1E5V/sec and 1E10V/sec or between 1 mA/sec and 1E8A/sec in one or more embodiments.

The end of the second leading portion of the set pulse 420 corresponds to the temperature Tn there PCA has maximum nucleation probability multiplied by the coefficient Kn. The temperature Tn of the maximum nucleation probability is between 50 deg. C and 450 deg. C for different PCA. The coefficient Kn is between 1 and 3. The amplitude of the second leading portion of the set pulse 420 (current between A420 and A410) is between 1 uA and 1 mA in one or more embodiments.

The duration of the second leading portion of the set pulse 420 (time between t410 and t420) corresponds to the development of nuclei in PCA. The duration of the second leading portion of the set pulse 420 is below 1 us in one or more embodiments. The duration of the second leading portion of the set pulse 420 is below 100 ns in one or more preferred embodiments.

The parameters of the second leading portion of the set pulse 420 are selected in the way that ratio A420/t420 is below 1E6A/sec in one or more embodiments. The parameters of the second leading portion of the set pulse 420 are selected in the way that ratio A420/t420 is equal to zero in one or more embodiments.

The end of the third leading portion of the set pulse 430 corresponds to the temperature Tx there PCA has maximum crystallization probability multiplied by the coefficient Kx. The temperature Tx of the maximum nucleation probability is between 70 deg. C. and 600 deg. C. for different PCA. The coefficient Kx is between 1 and 3. The amplitude of the third leading portion of the set pulse 430 (current between A430 and A420) is between 10 uA and 2 mA in one or more embodiments.

The duration of the third leading portion of the set pulse 430 (time between t420 and t430) corresponds to the formation of crystallization centers from most of the nuclei, and the growth of crystals on these formed centers in PCA. The duration of the third leading portion of the set pulse 430 is below 1 us in one or more embodiments.

From a practical standpoint, it is important that the rate of the formation of crystallization centers from most of the nuclei, and the growth of crystals be “just right”. If it is very slow, the PCM will have pure performance. Conversely, if this rate is too fast, the heat evolved during crystallization may not be dissipated to the surroundings fast enough to avoid detrimental thermal gradients that may result in stresses sufficient to reduce the PCM endurance. Therefore, the duration of the third leading portion of the set pulse 430 is below 200 ns in one or more preferred embodiments.

The parameters of the third leading portion of the set pulse 430 are selected in the way that ratio A430/t430 is below 5E6A/sec in one or more embodiments. The parameters of the third leading portion of the set pulse 430 are selected in the way that ratio A430/t430 is equal to zero in one or more embodiments.

The variation of the amplitude A440 of the intermediate flat portion of the set pulse 440 is between −20% and +20% of the value of the amplitude A440 in one or more embodiments. The variation of the amplitude A440 of the flat portion of the set pulse 440 is constant between −3% and +3% of the value of the amplitude A440 in one or more preferred embodiments. The amplitude of the flat portion of the set pulse 440 depends on the PCA and construction of PCM cell. The value of the amplitude A440 of the flat portion of the set pulse 440 is between 10 uA and 2 mA in one or more embodiments.

The duration of the flat portion of the set pulse 440 (time between t430 and t440) corresponds to the crystal grow and the coalescence of the crystals in PCA. The duration of the flat portion of the set pulse 440 is below 1 us in one or more embodiments. The duration of the flat portion of the set pulse 440 is below 500 ns in one or more preferred embodiments.

The parameters of the intermediate flat portion of the set pulse 440 are selected in the way that ratio A440/t440 is below 1A/sec in one or more embodiments. The parameters of the intermediate flat portion of the set pulse 440 are selected in the way that ratio A440/t440 is equal to zero in one or more preferred embodiments.

The end of the first trailing portion of the set pulse 450 corresponds to the stabilization of morphology of nano-crystals in PCA. The amplitude of the first trailing portion of the set pulse 450 (current between A440 and A450) is between 10 uA and 2 mA in one or more embodiments.

The duration of the first trailing portion of the set pulse 450 (time between t450 and t440) corresponds to the time is below 500 ns in one or more embodiments. The duration of the first trailing portion of the set pulse 450 is below 20 ns in one or more preferred embodiments.

The parameters of the first trailing portion of the set pulse 450 are selected in the way that ratio A450/t450 is between 20A/sec and 2E7A/sec in one or more embodiments.

The end of the second trailing portion of the set pulse 460 corresponds to cooling of nano-crystalline PCA. The amplitude of the first trailing portion of the set pulse 460 (current between A450 and zero) is between 100 uA and 1 mA in one or more embodiments. The duration of the second trailing portion of the set pulse 460 (time between t460 and t450) corresponds to the time is below 500 ns in one or more embodiments. The duration of the second trailing portion of the set pulse 460 is below 10 ns in one or more preferred embodiments.

The parameters of the second trailing portion of the set pulse 450 are selected in the way that ratio A460/t460 is between 2E2A/sec and 1E8A/sec in one or more embodiments. The minimal current during the set pulse 400 exceeds the threshold switching current of PCM. The maximum current during the set pulse 400 is below current that brings PCM to the melting temperature Tm of PCA.

The portions of the profile 410-460 shown in FIG. 4A can be linear, or non-linear, step-like or other complex patterns in one or more embodiments.

The parameters A410/t410, A420/t420, and A430/t430 of the segments of the leading portion of the set pulse 400 can be equal or different in one or more embodiments. In one or more preferred embodiments all these three parameters are equal 1E3A/sec or greater.

The parameters A450/t450 and A460/t460 of the segments of the trailing portion of the set pulse 400 can be equal or different in one or more embodiments. Absolute value of both these parameters can be equal to the similar parameters of the segments of the leading portion of the set pulse 400 in one or more preferred embodiments.

The durations of each portion 410-460 of the set pulse 400 can be zero in one or more embodiments. The whole duration of the set pulse 400 can be between 1 ns and 1 us in one or more embodiments.

FIGS. 4B-4J show various programming set pulse profiles, in accordance with one or more embodiments of the present invention. Anybody skilled in the art can easily understand these set pulses after learning of the reset pulse shown in FIG. 4A and described above.

RESET State.

The programming from set (crystalline) state to reset state by electrical pulses includes heating of PCA to the melting temperature, its fusion, and fast quenching below the glass transition temperature. Usually the fast cooling is the bottleneck for using PCM from PCA like Ge—Sb—Te in MLS because of drift of parameters of mostly amorphous PCA. Moreover fast transition of melting point leads to overheat of PCA and non-uniform temperatures in active PCA volume that causes phase separation of PCA material and low PCM endurance.

The programming reset pulse profile describes the shape of the pulse as shown in FIG. 4.

The reset pulses shown in FIG. 5 start at time zero and zero amplitude and finish at zero amplitude. Any arbitrary points can be selected for the reset pulse start and end in one or more embodiments.

Referring to FIG. 5A, the end of the first leading portion of the reset pulse 510 corresponds to the heating PCM to the minimal melting temperature. The melting temperature Tm is between 270 deg. C. and 1200 deg. C. for different PCA. The amplitude of the first leading portion of the reset pulse 510 (value between zero and A510) is between 10 uA and 2 mA in one or more embodiments.

The duration of the first leading portion of the reset pulse 510 (time between zero and t510) is between 1 ps and 10 ns in one or more embodiments. The duration of the first leading portion of the reset pulse 510 is below 3 ns in one or more preferred embodiments. The parameters of the first leading portion of the reset pulse 510 are selected in the way that ratio A510/t510 is between 1E3A/sec and 1E9A/sec in one or more embodiments.

The second leading portion of the reset pulse 520 corresponds to the latent heat of PCA. The amplitude of the second leading portion of the reset pulse 520 (current between A520 and A510) is between 1 uA and 100 uA in one or more embodiments.

The duration of the second leading portion of the reset pulse 520 (time between t510 and t520) is between 2 ns and 200 ns in one or more embodiments. The duration of the second leading portion of the reset pulse 520 is below 50 ns in one or more preferred embodiments.

The parameters of the second leading portion of the reset pulse 520 are selected in the, way that ratio A520/t520 is smaller than ration A520/t520, hence reset pulse 500 does not produce significant non-uniform overheating in PCM. The ration A520/t520 is below 1E6A/sec in one or more embodiments.

The variation of the amplitude A530 of the intermediate flat portion of the reset pulse 550 is between −20% and +20% of the value of the amplitude A550 in one or more embodiments. The variation of the amplitude A550 of the flat portion of the reset pulse 550 is constant between −3% and +3% of the value of the amplitude A550 in one or more preferred embodiments. The value of the amplitude A550 of the flat portion of the reset pulse 550 corresponds to the PCA melting point Tm multiplied by the coefficient Km. The coefficient Km is between 1 and 1.6. The value of the amplitude A550 of the flat portion of the reset pulse 550 is between 50 uA and 2 mA in one or more embodiments.

The duration of the flat portion of the reset pulse 550 (time between t530 and t550) corresponds to the good mixing of atoms in the melt that leads to the melt homogenization. The duration of the flat portion of the reset pulse 550 is below 50 ns in one or more embodiments. The duration of the flat portion of the reset pulse 550 is below 5 ns in one or more preferred embodiments.

The parameters of the intermediate flat portion of the reset pulse 550 are selected in the way that ratio A550/t550 is below 1A/sec in one or more embodiments. The parameters of the intermediate flat portion of the reset pulse 550 are selected in the way that ratio A440/t440 is equal to zero in one or more preferred embodiments.

The end of the first trailing portion of the reset pulse 540 corresponds to the quenching PCA below the glass transition temperature Tg. The amplitude of the first trailing portion of the reset pulse 550 (current between A530 and A540) is between 30 uA and 2 mA in one or more embodiments.

The duration of the first trailing portion of the reset pulse 550 (time between t550 and t550) corresponds to the time is below 50 ns in one or more embodiments. The duration of the first trailing portion of the reset pulse 540 is below 5 ns in one or more preferred embodiments.

The parameters of the first trailing portion of the reset pulse 550 are selected in the way that ratio A550/t550 is above 1E6A/sec in one or more embodiments. The ratio A550/t550 is above 1E7A/sec in one or more preferred embodiments.

The end of the second trailing portion of the reset pulse 550 corresponds to annealing of PCA that allows decrease drift of parameters (e.g., resistance) in reset PCM. The amplitude of the second trailing portion of the reset pulse 560 (current between A550 and 0) is between 1 uA and 500 uA in one or more embodiments.

The duration of the second trailing portion of the reset pulse 550 (time between t550 and t540) is below 10 us in one or more embodiments. The duration of the second trailing portion of the reset pulse 560 is below 500 ns in one or more preferred embodiments. The parameters of the second trailing portion of the reset pulse 550 are selected in the way that ratio A550/t550 is below 1E5A/sec in one or more embodiments. The parameters of the second trailing portion of the reset pulse 550 are selected in the way that ratio A550/t550 is equal to zero in one or more embodiments.

The end of the third trailing portion of the reset pulse 560 corresponds to the ambient temperature. The amplitude of the third trailing portion of the reset pulse 560 (current between A550 and zero) is between 10 uA and 1 mA in one or more embodiments. The duration of the third trailing portion of the reset pulse 560 (time between t550 and t560) is between 10 ns and 1 ps in one or more embodiments. The duration of the third trailing portion of the reset pulse 560 is below 1 ns in one or more preferred embodiments. The parameters of the third trailing portion of the reset pulse 560 are selected in the way that ratio A560/t560 is between 1E3A/sec and 1E10A/sec in one or more embodiments.

The minimal current during the reset pulse 500 exceeds the minimal melting temperature Tm of PCA. The maximum current during the reset pulse 500 is below the average melting temperature Tm of PCA multiplied by factor Rm, where 1<Rm<3.

The portions of the profile 510-560 shown in FIG. 5A can be linear, or non-linear, step-like or other complex patterns in one or more embodiments. The parameters A510/t510, A520/t520, and A530/t530 of the segments of the leading portion of the reset pulse 500 can be equal or different in one or more embodiments. In one or more preferred embodiments all these three parameters are equal 1E3A/sec or greater.

The parameters A550/t550 and A560/t560 of the segments of the trailing portion of the reset pulse 500 can be equal or different in one or more embodiments. Absolute value of both these parameters can be equal to the similar parameters of the leading portion of the reset pulse 500 in one or more preferred embodiments.

The durations of each portion 510-560 of the reset pulse 500 can be zero in one or more embodiments. The whole duration of the reset pulse 500 can be between 1 ns and 100 ns in one or more embodiments.

FIGS. 5B-5G show various programming reset pulse profiles in accordance with one or more embodiments of the present invention. Anybody skilled in the art can easily understand these reset pulses after learning of the reset pulse shown in FIG. 5A and described above.

FIG. 6 shows comparison of the set pulse 499 and the reset pulse 599 with the same triangle shape. Anybody skilled in the can easily recognize that a) the amplitude of the reset pulse is higher than the set pulse; b) both pulses have the only one leading portion and the only one trailing portion and the duration of the intermediate portion is essentially zero; c) both pulses have the same rate of the amplitude change during the leading portions; d) both pulses have the same rate of the amplitude change during the trailing portions; e) duration of the trailing portions for both set and reset pulses is essentially zero; f) the amplitude of the set pulse brings PCA above the crystallization temperature Tx while the amplitude of the reset pulse brings PCA above the melting temperature Tm.

Memory array consist of plurality of PCM cells electrically connected with the write circuit as shown in FIG. 6. The write circuit provides set and reset pulses described in the previous sections. The memory array and the write circuit are coupled with an interface device, e.g. with computer or cellular phone. Anybody skilled in the art can easily choose or design the specially constructed or/and general-purpose write circuit and memory array.

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of portions and/or steps and/or segments may be exaggerated for clarity.

It will be understood that, although the terms first, second, third etc. may be used herein to describe various portions and/or steps and/or segments, these portions and/or steps and/or segments should not be limited by these terms. These terms are only used to distinguish one portion and/or step and/or segment from another portion and/or step and/or segment. Thus, a first portion and/or step and/or segment discussed below could be termed a second portion and/or step and/or segment without departing from the teachings of the present invention.

Temporary relative terms, such as “after,” and “before” and the like, may be used herein for ease of description to describe one portions and/or steps and/or segments or feature's relationship to another portions and/or steps and/or segments(s) or feature(s) as illustrated in the figures.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated portions and/or steps and/or segments and/or features, but do not preclude the presence or addition of one or more other portions and/or steps and/or segments, and/or features thereof.

Example embodiments of the present invention are described herein with reference to drawings that are schematic illustrations of idealized embodiments of the present invention. As such, variations from the shapes of the illustrations as a result, for example, of a noise or a signal's attenuation in circuits and memory array, are to be expected. Thus, example embodiments of the present invention should not be construed as limited to the particular shapes of regions illustrated herein but are to include deviations in shapes that result, for example, from signals processing. Thus, the portions illustrated in the figures are schematic in nature and their shapes are not intended to illustrate the actual shape of a signal portion and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein in connection with the description of the invention, the term “about” means+/−10%. By way of example, the phrase “about 100” indicates a range of between 90 and 110. With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form portions and/or steps and/or segments of the invention are useful operations. The invention also relates to a device or an apparatus for performing these operations. The apparatus may be specially constructed for the required purposes, or it may be a general-purpose apparatus. In particular, various general-purpose or apparatus may be used with computer programs written in accordance with the teachings herein, or it may be more convenient to construct a more specialized apparatus to perform the required operations.

It will be further appreciated that the instructions represented by the operations in the above figures are not required to be performed in the order illustrated, and that all the processing represented by the operations may not be necessary to practice the invention. Further, the processes described in any of the above figures can also be implemented in the specially constructed or/and general-purpose apparatus.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

While the above description contains specificities, these should not be construed as limitations on the scope of any embodiment, but as exemplifications of the presently preferred embodiments thereof. Many other ramifications and variations are possible within the teachings of the various embodiments. Thus the scope of the invention should be determined by the appended claims and their legal equivalents, and not by the examples given.

### CONCLUSION

Proposed set pulses allows to achieve uniform set resistance for PCM cells in big array without spending large energy for programming and without degradation of PCA by electro-diffusion of electrodes into molten material. The reduced variation of set resistance increases stability in different operating conditions (e.g., ambient temperature, etc.) and can also compensate for semiconductor manufacturing process variations (e.g., PCA thickness variations, PCA material variations, contact size, etc.).

Proposed reset pulses allows to achieve high endurance of PCM memory, stable value of reset resistance that does not change with cycling, and low drift of reset parameters with time.

I claim:

1. A method for a phase change memory programming, providing:
a pulse that has at least one leading portion with essentially non-zero duration,
followed by an intermediate portion, and then
followed by at least one trailing portion
in order to transform phase-change alloy into low-resistance mostly crystalline set state.

2. The method of claim 1 wherein duration of the leading portion of the set pulse is between 5 ns and 1 us.

3. The method of claim 1 wherein the set pulse amplitude does not melt phase change alloy.

4. The method of claim 1 wherein the leading portion of the set pulse has 2 or more segments.

5. The method of claim 1 wherein the leading portion of the set pulse has 3 segments.

6. The method of claim 4 wherein duration of the leading portion segment is between 5 ns and 1 us.

7. The method of claim 1 wherein duration of the trailing portion of the set pulse is between 0 and 1 us.

8. The method of claim 1 wherein the trailing portion of the set pulse has 2 or more segments.

9. The method of claim 8 wherein duration of the trailing portion segment is shorter than 1 us.

10. The method of claim 1 wherein duration of the intermediate portion of the set pulse is shorter than 1 us.

11. The method of claim 1 wherein a change of amplitude during the intermediate portion of the set pulse is below 20% of the amplitude of this portion.

12. The method of claim 1 wherein amplitude of the set pulse is between 1 uA and 2 mA.

13. The method of claim 1 wherein a threshold switching occurs during the leading portion or one of its segments.

14. The method of claim 1 wherein a nucleation occurs during the leading portion or one of its segments.

15. The method of claim 1 wherein a crystallization occurs mostly during the leading portion or one of its segments.

16. The method of claim 1 wherein a crystal growth and coalescence of crystals occurs mostly during the intermediate portion of the set pulse.

17. The method of claim 1 wherein a stabilization of morphology of nano-crystals occurs mostly during the trailing portion or one of its segments.

18. A method for a phase change memory programming, providing:
a pulse that has at least one leading portion with essentially non-zero duration,
followed by an intermediate portion, and then
followed by at least one trailing portion
in order to transform phase-change alloy into high-resistance mostly amorphous reset state.

19. The method of claim 18 wherein duration of the leading portion of the reset pulse is between 0.1 ns and 100 ns.

20. The method of claim 18 wherein the reset pulse amplitude melts phase change alloy.

21. The method of claim 18 wherein the leading portion of the reset pulse has 2 or more segments.

22. The method of claim 21 wherein duration of the leading portion segment is between 0.1 ns or 100 ns.

23. The method of claim 18 wherein duration of the trailing portion of the reset pulse is between 0 and 50 ns.

24. The method of claim 18 wherein the trailing portion of the reset pulse has 2 or more segments.

25. The method of claim 18 wherein the trailing portion of the reset pulse has 3 segments.

26. The method of claim 24 wherein duration of the trailing portion segment is shorter than 50 ns.

27. The method of claim 18 wherein duration of the intermediate portion of the reset pulse is shorter than 50 ns.

28. The method of claim 18 wherein a change of amplitude during the intermediate portion of the reset pulse is below 20% of the amplitude of this portion.

29. The method of claim 18 wherein amplitude of the reset pulse is between 10 uA and 3 mA.

30. The method of claim 18 wherein a temperature within phase change alloy reaches the melting point of this alloy during the leading portion or one of its segment.

31. The method of claim 18 wherein a melt fusion occurs mostly during the leading portion or one of its segments.

32. The method of claim 18 wherein a mixing and a homogenization of the melt occurs mostly during the intermediate portion of the reset pulse.

33. The method of claim 18 wherein quenching of phase change alloy into mostly amorphous phase occurs mostly during the trailing portion or one of its segments.

34. The method of claim 18 wherein annealing of amorphous phase change alloy occurs mostly during the trailing portion or one of its segments.

35. The method of claim 4 wherein rates of the amplitude change are different during various segment of the leading portion of the set pulse.

36. The method of claim 8 wherein rates of the amplitude change are different during various segment of the trailing portion of the set pulse.

37. The method of claim 21 wherein rates of the amplitude change are different during various segment of the leading portion of the reset pulse.

38. The method of claim 24 wherein rates of the amplitude change are different during various segment of the trailing portion of the reset pulse.

39. The method of claim 4 wherein rate of the amplitude change during the first segment of the leading portion of the set pulse is between 1E5V/sec and 1E10V/sec.

40. The method of claim 4 wherein rate of the amplitude change during the first segment of the leading portion of the set pulse is between 1 mA/sec and 1E8A/sec.

41. The method of claim 4 wherein rate of the amplitude change during the second segment of the leading portion of the set pulse is below 1E6A/sec.

42. The method of claim 4 wherein rate of the amplitude change during the third segment of the leading portion of the set pulse is below 5E6A/sec.

43. The method of claim 8 wherein rate of the amplitude change during the first segment of the trailing portion of the set pulse is between 20 A/sec and 2E7A/sec.

44. The method of claim 8 wherein rate of the amplitude change during the second segment of the trailing portion of the set pulse is between 2E2A/sec and 1E8A/sec.

45. The method of claim 21 wherein rate of the amplitude change during the first segment of the leading portion of the reset pulse is between 1E3A/sec and 1E9A/sec.

46. The method of claim 21 wherein rate of the amplitude change during the second segment of the leading portion of the reset pulse is below 1E6A/sec.

47. The method of claim 24 wherein rate of the amplitude change during the first segment of the trailing portion of the reset pulse is above 1E7A/sec.

48. The method of claim 24 wherein rate of the amplitude change during the second segment of the trailing portion of the reset pulse is below 1E5A/sec.

49. The method of claim 24 wherein rate of the amplitude change during the third segment of the trailing portion of the reset pulse is between 1E3A/sec and 1E10A/sec.

50. An apparatus comprising:
a phase change memory; and
a write circuit coupled with the phase change memory; and
other interface devices coupled with the phase change memory and the write circuit.
